(19) United States
(12) Patent Application Publication
(10) Pub. No.: US 2016/0016790 A1
(43) Pub. Date: Jan. 21, 2016

(54) Miniaturized Component and Method for the Production Thereof

(71) Applicant: EPCOS AG, München (DE)

(72) Inventor: Stephan Marksteiner, Neubiberg (DE)

(21) Appl. No.: 14/773,270

(22) PCT Filed: Feb. 5, 2014
(86) PCT No.: PCT/EP2014/052250

§ 371 Date: Sep. 4, 2015

(30) Foreign Application Priority Data
Mar. 6, 2013 (DE) 10 2013 102 213.8

(51) Int. Cl. B81B 7/00; B81C 1/00

(52) U.S. Cl. CPC B81B 7/0041; B81C 1/00293; B81C 2203/0136; B81C 2203/0145; B81B 2207/07

(57) ABSTRACT

An encapsulated component and a method for producing an encapsulated component are specified. The component includes a carrier substrate, a functional structure, a thin-film cover and a reinforcement layer comprising glass. The carrier substrate, the thin-film cover and the reinforcement layer together enclose a cavity around at least parts of the functional structure.

This patent application is a national phase filing under section 371 of PCT/EP2014/052250, filed Feb. 5, 2014, which claims the priority of German patent application 10 2013 102 213.8, filed Mar. 6, 2013, each of which is incorporated herein by reference in its entirety.

### TECHNICAL FIELD

The invention relates to miniaturized components, e.g., MEMS components or micro acoustic components, and methods for producing such components.

### BACKGROUND

The miniaturization of components is constrained by the continuous trend toward integration of additional functions into portable devices such as, e.g., cellular phones or other wireless communication devices in which the components are incorporated. Such components can comprise, e.g., MEMS structures such as MEMS switches or filters operating with acoustic waves as functional structures.

There are functional structures which have to be decoupled from their environment in order that they can operate as intended. A decoupling can consist in a hermetic encapsulation or in a mechanical decoupling. Components operating with acoustic waves, e.g., SAW components (SAW=surface acoustic wave), BAW components (BAW=bulk acoustic wave) or GBAW components (GBAW=guided bulk acoustic wave) generally require both a hermetic encapsulation and a mechanical decoupling of the acoustically active regions.

Furthermore, steps for producing components can include molding processes, wherein a molding compound is applied under the action of pressure. The components should therefore be mechanically sufficiently stable and pressure-resistant.

The patent specification U.S. Pat. No. 7,268,436 B2 discloses wafer level packages (WLP) with cover wafer for covering functional structures.

The patent specification U.S. Pat. No. 7,692,317 B2 discloses encapsulation methods without a cover wafer.

The patent specification U.S. Pat. No. 7,344,907 discloses encapsulated components containing MEMS structures.

One possibility for encapsulation consists in a TFP (TFP=thin-film package).

### SUMMARY

Embodiments of the present invention provide a component that is compatible with the continuous trend toward miniaturization, that is to say is of small construction. The component enables a hermetically impermeable and mechanically stable encapsulation, is suitable for accommodating structures operating with acoustic waves and is producible expediently, that is to say by simple method steps. Further embodiments specify a method for producing such a component.

The component comprises a carrier substrate and a functional structure on the carrier substrate. It furthermore comprises a thin-film cover above the functional structure and a reinforcement layer comprising glass above the thin-film cover. The carrier substrate, the thin-film cover and the reinforcement layer together enclose a cavity. At least one part of the functional structure is arranged in the cavity.

In this case, that part of the functional structure which is arranged in the cavity can be spaced apart from the inner walls and/or the top of the cavity. A mechanical decoupling between the structure and the cover is then obtained.

In this case, the thin-film cover can be formed by a layer of a so-called TFP.

It has been recognized that although conventional TFPs enable a small and primarily low design, conventional TFPs cannot readily produce an excellent hermetic seal or a mechanically stable cover suitable for molding.

Applying a reinforcement layer comprising glass improves the hermeticity and increases the mechanical stability, without enlarging the structural size too much.

In this case, the cavity can be arranged around the functional structures such that a micromechanical mobility of the structures is not impaired by the housing. The functional structure is rather mechanically fixed but nevertheless decoupled from the housing and protected against disadvantageous environmental influences—e.g., dust or other materials which might deposit on the functional structure and, e.g., detune the operating frequency.

In one embodiment, the functional structure is an MEMS structure and/or a micro acoustic structure. In particular, an SAW structure, a BAW structure or a GBAW structure is appropriate as the functional structure.

In one embodiment, an opening is structured in the thin-film cover. The opening in the thin-film cover is closed by the reinforcement layer. It is also possible to provide two or more openings, closed by the reinforcement layer, in the thin-film cover. The opening or the multiplicity of openings in the thin-film cover can serve, during the process for producing the component, to remove a sacrificial layer under the thin-film cover. In order to obtain a good hermetic seal, a reinforcement layer comprising glass is particularly well suited, owing to the adjustability of the viscosity. In this case, the viscous properties of the reinforcement layer are ideally chosen such that the material of the reinforcement layer completely covers the openings and, if appropriate, also penetrates into the openings, without penetrating through the openings and filling the cavity.

In this case, the arrangement of the openings can be chosen such that a uniform distribution of openings over the area of the thin-film cover is obtained. The openings can be arranged in a square, rectangular or hexagonal pattern or in radial alignment with one another.

In this case, the openings can have a radius that increases or decreases from the inner side outward. It is possible to form the thin-film cover such that material of the thin-film cover is applied only where no opening is intended to be present. However, it is also possible to apply the thin-film cover areally above the functional structure and to remove it locally, at the locations of the later openings, e.g., by means of an etching process.

Conventional lithographic methods can be used for producing the thin-film cover and forming the openings.

In one embodiment, the thin-film cover comprises a material selected from: SiO₂ (silicon dioxide), SiₓN_{y} (silicon nitride), Al₂O₃ (aluminum oxide). The carrier substrate can comprise a material selected from glass and Si (silicon).

Particularly if the functional structure has an electrical function and comprises electrode structures, it can be advantageous to use a high-resistance material as carrier material. Alternative materials for the carrier substrate are likewise all vitreous or crystalline solids having a high electrical resistivity.

In one embodiment, the cavity has a width of at least 10 μm and a height of less than 100 μm. The thin-film cover has a thickness of less than 5 μm. The reinforcement layer has a thickness of less than 50 μm.

Such a thin-film cover by itself might possibly not withstand a customary molding pressure of approximately 100 bar. In conjunction with the reinforcement layer, however, even if the width is relatively large relative to the structural height, a stable encapsulation that withstands such pressures can be obtained.

It is furthermore possible for the functional structure to have a width of approximately 90 μm. The cavity can have a width that is between 10 and 20 μm above the width of the functional structure. The functional structure can have a height of between 2 and 3 μm. The distance between the functional structure and the top of the cavity, that is to say the inner area of the thin-film cover, can be between 2 and 3 μm. The thickness of the thin-film cover can be between 1 and 2 μm. The thickness of the reinforcement layer can be between 10 and 30 μm. Particularly if the reinforcement layer is planarized, the thickness of the reinforcement layer can vary locally.

It is possible for the reinforcement layer to bear only on the thin-film cover. However, it is also possible for the thin-film cover to be structured such that the reinforcement layer bears at least partly directly on the carrier substrate, in order to ensure a more stable connection of the component.

In one embodiment, the functional structure is interconnected with a connection pad via a line. The connection pad itself is covered neither by the thin-film cover nor by the reinforcement layer and is suitable for interconnecting the component with an external circuit environment, e.g., via a bump connection.

A method for producing an encapsulated component comprises the following steps: providing a carrier substrate, structuring a functional structure on the carrier substrate, applying a sacrificial layer above the functional structure, applying a thin-film cover having an opening above the sacrificial layer, removing the sacrificial layer through the opening in the thin-film cover, and applying the reinforcement layer above the thin-film cover.

In one embodiment of the method, the sacrificial layer is an organic material and is suitable for removal by dry ashing. The dry ashing can be carried out, e.g., by means of molecular or atomic oxygen, ozone or oxygen plasma.

In one embodiment, applying the reinforcement layer comprises the following steps: applying a glass paste, closing the opening in the thin-film cover, and firing the glass paste.

In one embodiment, the glass paste comprises glass frit composed of a suspension of fine glass particles in a binder matrix. The glass paste is applied to the thin-film cover by blade coating. The binder decomposes completely during the firing of the glass paste.

In this case, the binder can decompose under the influence of temperature in H₂O and/or in CO₂.

In this case, the composition of the glass paste is chosen such that the glass that arises during the firing of the glass paste covers, and if appropriate at least partly fills, the opening or the openings in the thin-film cover. Ideally, the glass does not penetrate into the cavity. At all events, penetrating glass must be prevented from running down on the inner side of the cavity and coming into contact with the functional structure.

The process of applying the glass paste can be carried out cost-effectively using a blade coating mask. The surface tension of the glass component of the reinforcement layer is ideally set such that later structuring of the reinforcement layer is not necessary.

A temperature of between 250° C. and 350° C. can be set for firing the glass paste.

The various embodiments can interact in arbitrary combination in order to satisfy one or more requirements.

### BRIEF DESCRIPTION OF THE DRAWINGS

The component and the method for producing a component and further exemplary embodiments are explained below with reference to schematic figures.

In the figures:

FIG. 1 shows an encapsulated component with a functional structure in a cavity.

FIG. 2 shows an encapsulated component with a BAW structure.

FIG. 3 shows an encapsulated component with an SAW structure.

FIG. 4 shows an encapsulated component with openings in the thin-film cover.

FIG. 5 shows an encapsulated component in which the thin-film cover is covered by a molding compound.

FIG. 6 shows an intermediate product during the production of an encapsulated component.

FIG. 7 shows a further intermediate product during the production of an encapsulated component.

FIG. 8 shows a further intermediate product during the production of an encapsulated component.

FIG. 9 shows a further intermediate product during the production of an encapsulated component.

FIG. 10 shows a further intermediate product during the production of an encapsulated component.

FIG. 11 shows an encapsulated component in which openings in the thin-film cover are covered by a reinforcement layer.

FIG. 12 shows an encapsulated component in which material of the reinforcement layer at least partly fills openings in the thin-film cover.

FIG. 13 shows an encapsulated component with a solder ball for electrical interconnection.

### DETAILED DESCRIPTION OF ILLUSTRATIVE EMBODIMENTS

FIG. 1 shows an encapsulated component VB comprising a substrate SU, on which a functional structure FS is arranged. A cavity H is formed by a thin-film cover DSA and a reinforcement layer VS applied thereabove, in which cavity the functional structure FS can operate in a manner shielded hermetically from the surrounding atmosphere. In this case, the cavity is shaped such that the functional structure FS does not touch its cover, that is to say the thin-film cover DSA. This is necessary, for example, in the case of components operating with acoustic waves.

The reinforcement layer VS improves the hermeticity of the encapsulation and in particular the mechanical stability of the entire component.

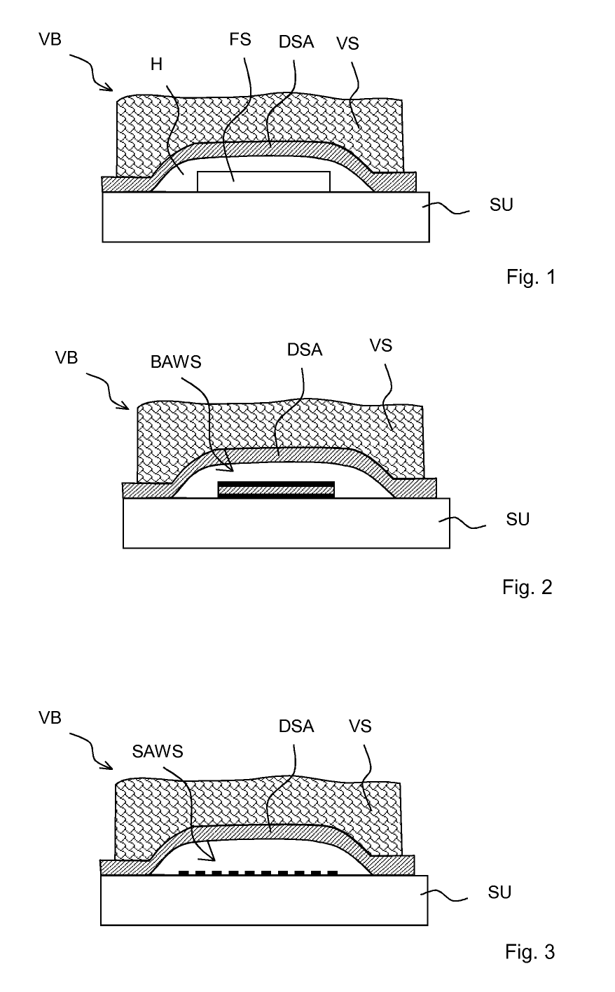

FIG. 2 shows one embodiment of an encapsulated component VB in which the functional structure is embodied as a BAW structure BAWS. The BAW structure BAWS then comprises at least one piezoelectric layer between two electrode layers.

FIG. 3 shows one configuration of the encapsulated component VB, wherein the functional structure is embodied as an SAW structure SAWS. In this case, finger-shaped electrode structures—shown here in cross section—are arranged on a piezoelectric material and interconnected in each case with a bus bar.

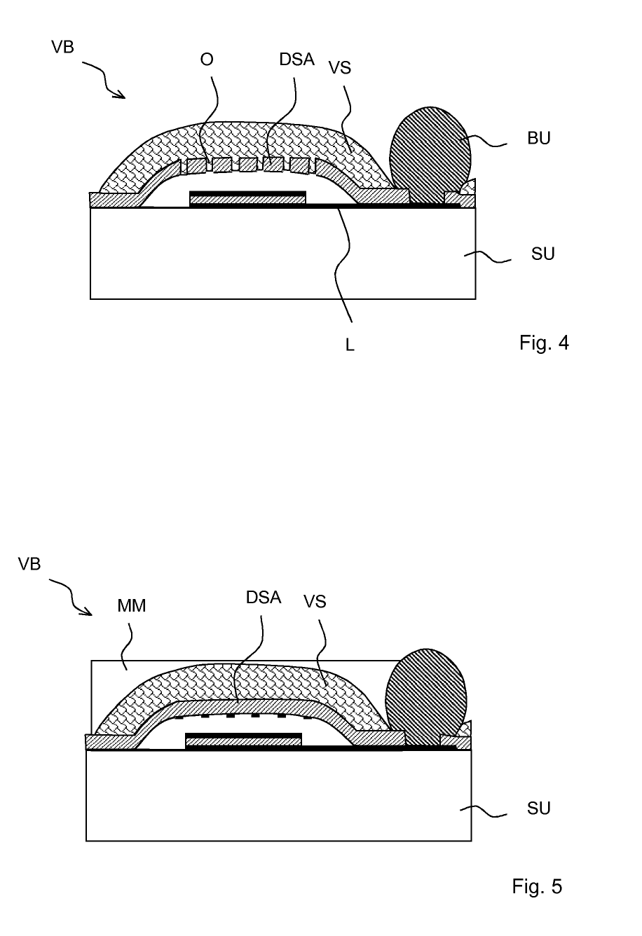

FIG. 4 shows one embodiment of the encapsulated component VB, wherein openings O are provided in the thin-film cover DSA. The openings O are covered and sealed by the reinforcement structure VS. Merely by way of example, the functional structure is embodied as a BAW structure. The bottom electrode of the BAW structure is connected to a solder ball BU via a lead L. By means of the solder ball BU, an interconnection with an external circuit environment can be achieved, for example, via a bump connection.

FIG. 5 shows one embodiment of the encapsulated component VB, wherein at least parts of the component are covered by a molding compound MM. The molding compound MM furthermore improves the hermeticity, can be planarized in order to obtain defined geometrical shapes of the component, and furthermore reinforces the mechanical stability of the component.

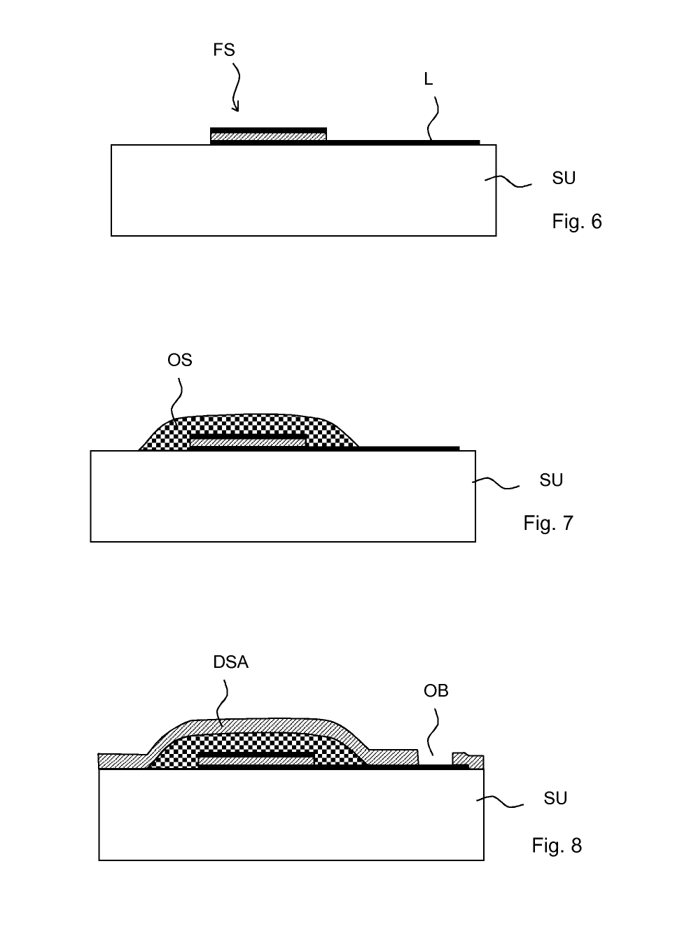

FIG. 6 shows an intermediate product of an encapsulated component in which component structures of a BAW resonator as functional structure FS and a lead L are arranged on a substrate SU.

FIG. 7 shows a later method stage, in which the functional structure is covered by a sacrificial layer OS. The shape of the sacrificial layer substantially defines the later shape of the cavity.

FIG. 8 shows the result of a further method step, wherein the thin-film cover DSA is arranged above the sacrificial layer and above parts of the substrate. Conventional methods for producing thin films, e.g., sputtering, thermal evaporation, CVD (chemical vapor deposition), PVD (physical vapor deposition), PLD (pulsed laser deposition) or MBE (molecular beam epitaxy), can be used for the arrangement of the thin-film cover DSA. In this case, the thin-film cover DSA can, for its part, comprise two or more individual layers.

In this case, an open region OB is kept free in order that a connection pad can be produced later.

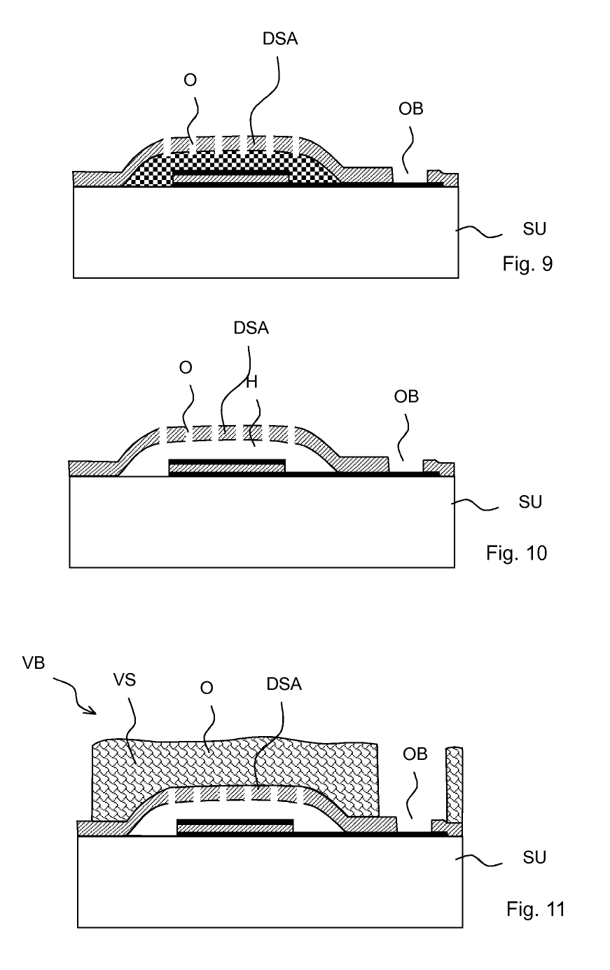

FIG. 9 shows the result of a further method step, in which openings O have been structured in the thin-film cover DSA.

FIG. 10 shows the result of a further method step, in which the sacrificial layer has been removed through the openings O in the thin-film cover DSA. Measures such as wet or dry etching or ashing in an oxidizing atmosphere can be used for removing the sacrificial layer.

Instead of the sacrificial layer, there is now situated a cavity H in which the functional structure is now arranged, without touching parts of the cover.

FIG. 11 shows the result of a further method step, wherein material of the reinforcement layer VS is arranged above the thin-film cover DSA. This in turn involved dispensing with the deposition of material in the open region OB, in order to keep available an opening for later contacting. The process of applying the material of the reinforcement layer VS can be carried out, for example, by blade coating by means of a blade coating mask.

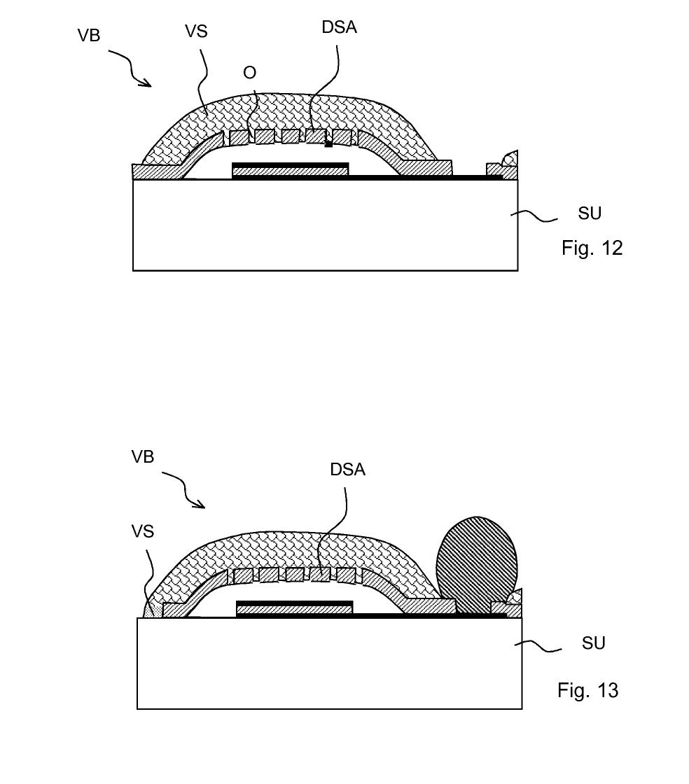

FIG. 12 shows the result of a method step in which the material of the reinforcement layer VS, that is to say, essentially the glass paste comprising glass particles in a binder matrix, was fired. As a result of the firing, the binder completely decomposes and a single-phase vitreous reinforcement layer VS remains which covers, seals and at least partly fills openings in the thin-film cover.

FIG. 13 shows one embodiment of the encapsulated component VB, wherein the thin-film cover DSA is structured such that the reinforcement layer VS touches the substrate SU in a region, such that the mechanical connection between the reinforcement layer VS and the substrate is reinforced.

An encapsulated component is not restricted to any of the embodiments described. Combinations of features and embodiments with further layers and cavities likewise constitute embodiments according to the invention.

1-10. (canceled)

11. An encapsulated component, comprising:
a carrier substrate;
a functional structure over the carrier substrate;
a thin-film cover above the functional structure; and
a reinforcement layer comprising glass above the thin-film cover, wherein the carrier substrate, the thin-film cover and the reinforcement layer together enclose a cavity, at least one part of the functional structure being arranged in the cavity.

12. The component according to claim 11, wherein the functional structure comprises a MEMS structure.

13. The component according to claim 11, wherein the functional structure comprises a micro acoustic structure.

14. The component according to claim 11, wherein an opening is structured in the thin-film cover, the opening being closed by the reinforcement layer.

15. The component according to claim 11, wherein the thin-film cover comprises a material selected from the group consisting of SiO₂, SiₓN_{y}, Al₂O₃, and wherein the carrier substrate comprises glass or Si.

16. The component according to claim 11, wherein:
the cavity has a width of at least 10 μm and a height of less than 100 μm;
the thin-film cover has a thickness of less than 5 μm; and
the reinforcement layer has a thickness of less than 50 μm.

17. The component according to claim 11, wherein the functional structure is interconnected with a connection pad via a line, the connection pad being covered by neither the thin-film cover nor the reinforcement layer.

18. A method for producing an encapsulated component, the method comprising:
structuring a functional structure on a carrier substrate;
applying a sacrificial layer above the carrier substrate;
applying a thin-film cover above the sacrificial layer, the thin-film cover having an opening;
removing the sacrificial layer through the opening in the thin-film cover; and
applying a reinforcement layer above the thin-film cover.

19. The method according to claim 18, wherein the sacrificial layer comprises an organic material and wherein removing the sacrificial layer comprises removing the sacrificial layer by oxidation through heating in an oxygen containing atmosphere.

20. The method according to claim 19, wherein applying the reinforcement layer comprises:
applying a glass paste;
closing the opening in the thin-film cover; and
firing the glass paste.

21. The method according to claim 20, wherein:
the glass paste comprises glass frit composed of a suspension of fine glass particles in a binder matrix;
the glass paste is applied to the thin-film cover by blade coating; and
the binder completely decomposes during the firing of the glass paste.

22. The method according to claim 18, wherein the sacrificial layer is applied above the functional structure.

23. The method according to claim 18, wherein the thin-film cover is applied directly on the sacrificial layer.

24. The method according to claim 18, wherein the reinforcement layer hermetically seals the opening in the thin-film cover.

25. An encapsulated component, comprising:
a carrier substrate;
a functional structure over the carrier substrate;
a thin-film cover above the functional structure;
a reinforcement layer comprising glass above the thin-film cover;
a solder ball located next to the reinforcement layer and electrically connected to the functional structure via a lead;
wherein the carrier substrate, the thin-film cover and the reinforcement layer together enclose a cavity;
wherein at least one part of the functional structure is arranged in the cavity; and
wherein the reinforcement layer touches the substrate such that a mechanical connection between the thin film cover and the substrate is reinforced.

26. The component according to claim 25, further comprising a lead extending from the functional structure to the solder ball.

27. The component according to claim 26, wherein the lead extends along a surface of the carrier.
